(19) United States
(12) Patent Application Publication
(10) Pub. No.: US 2012/0291849 A1
(43) Pub. Date: Nov. 22, 2012

(54) ENCLOSED PHOTOVOLTAIC DEVICE

(76) Inventor: Henry Kamahoahoa FATA, Beverly Hills, CA (US)

(21) Appl. No.: 13/471,379

(22) Filed: May 14, 2012

Related U.S. Application Data
(60) Provisional application No. 61/486,328, filed on May 16, 2011.

(51) Int. Cl. H01L 31/052

(52) U.S. Cl. 136/246

(57) ABSTRACT

The present invention is an enclosed photovoltaic device that includes one or more photovoltaic cells arranged in tandem, stacked apart vertically or horizontally from one another, encased or enclosed within a transparent four sided square shaped or box configure with one or more lenses embedded in each side that absorb sunlight or artificial light and a heat sink with a fan attached to the base of the device. As light enters the device, the light is magnified by the lenses, photons are absorbed by the cells and electricity is generated where it is directed to a power storage device or battery. The heat sink is attached to the base of the photovoltaic device to cool the device, where heat flow is directed out or absorbed. Each of the photovoltaic cells comprises of either a pair of electrodes, with each substantially transparent to the light received by the photovoltaic device.

This application claims priority to U.S. Provisional Application 61/486,328 filed on May 16, 2011, the entire disclosure of which is incorporated by reference.

### TECHNICAL FIELD & BACKGROUND

Solar energy has increasingly become an attractive source of energy for urban and rural areas and has been recognized as a relatively clean, renewable alternative form of energy. Solar energy in the form of sunlight, in one scheme, is converted into electrical energy by one or more solar cells. A more general term for devices that convert light into electrical energy is photovoltaic cells. Sunlight is a subset of light and therefore solar cells are a subset of photovoltaic cells. A photovoltaic cell includes a pair of electrodes and a light absorbing photovoltaic material in between the pair of electrodes. When the photovoltaic material is irradiated with light, electrons that have been confined to an atom in the photovoltaic material are released by light energy to move freely. Thus, free electrons and holes are generated. The free electrons and holes are efficiently separated so that electric energy is continuously extracted. Current commercial photovoltaic cells use a semiconductor photovoltaic material, which is typically silicon. And silicon for photovoltaic cells requires relatively high purity and stringent processing methods.

A solar panel (i.e., a photovoltaic module or photovoltaic panel) is a packaged interconnected assembly of a plurality of solar cells or photovoltaic cells. The solar panel can be used as a component of a larger photovoltaic system to generate and supply electricity in commercial and residential applications. A photovoltaic system (or PV system) is a system which uses one or more solar panels to convert sunlight into electricity. It includes multiple components, including the photovoltaic modules, mechanical and electrical connections and mountings and components to regulate and/or modify the electrical output. Due to the low voltage of an individual solar cell (i.e., typically ca. 0.5V), several cells are wired in series in the manufacture of a laminate. The laminate is assembled into a protective weatherproof enclosure, thus making a photovoltaic module or solar panel. A plurality of modules may then be strung together into a photovoltaic array. The electricity generated can be either stored, used directly (i.e., in an island or standalone plant) or fed into a large electricity grid powered by one or more central generation plants (i.e., a grid-connected or grid-tied plant) or combined with one or more domestic electricity generators to feed into a small grid (i.e., hybrid plant). A photovoltaic array (or solar array) is a linked collection of solar panels.

The power that one module can produce is seldom enough to meet requirements of a home or a business, so the modules are linked together to form an array. Most PV arrays use an inverter to convert the DC power produced by the modules into alternating current that can power lights, motors, and other loads. The modules in a PV array are usually first connected in series to obtain the desired voltage then the individual strings are then connected in parallel to allow the system to produce more current.

The present invention generally relates to a photovoltaic device. More specifically, the invention is an enclosed photovoltaic device.

It is an object of the invention to provide an enclosed photovoltaic device that reduces one or more strings or sizes of one or more arrays allowing more power for energy use and available space.

It is an object of the invention to provide an enclosed photovoltaic device that overcomes relatively high solar installation costs and a relatively high number of system components by maximizing electrical output using a plurality of enclosed solar cells or modules within a lens embedded transparent and reflective light amplified system.

It is an object of the invention to provide an enclosed photovoltaic device that includes a plurality of stacks of photovoltaic cells that are connected in series or parallel.

What is really needed is an enclosed photovoltaic device that reduces one or more strings or sizes of one or more arrays allowing more power for energy use and available space that overcomes relatively high solar installation costs and a relatively high number of system components by maximizing electrical output using a plurality of enclosed solar cells or modules within a lens embedded transparent and reflective light amplified system that includes a plurality of stacks of photovoltaic cells that are connected in series or parallel.

### BRIEF DESCRIPTION OF THE DRAWINGS

The present invention will be described by way of exemplary embodiments, but not limitations, illustrated in the accompanying drawings in which like references denote similar elements, and in which:

FIG. 1 illustrates an environmental front perspective view of an enclosed photovoltaic device, in accordance with one embodiment of the present invention.

FIG. 2 illustrates a cross-sectional view of line 1-1 from FIG. 1 of an enclosed photovoltaic device, in accordance with one embodiment of the present invention.

FIG. 3A illustrates a front view of a first photovoltaic panel with a plurality of vertical photovoltaic cells of an enclosed photovoltaic device, in accordance with one embodiment of the present invention.

FIG. 3B illustrates a front view of a second photovoltaic panel with a plurality of horizontal photovoltaic cells of an enclosed photovoltaic device, in accordance with one embodiment of the present invention.

FIG. 3C illustrates a front view of a solar cell of an enclosed photovoltaic device, in accordance with one embodiment of the present invention.

FIG. 4A illustrates a side view of an enclosed photovoltaic device with one bifocal photovoltaic panel, in accordance with one embodiment of the present invention.

FIG. 4B illustrates a side view of an enclosed photovoltaic device with two bifocal photovoltaic panels, in accordance with one embodiment of the present invention.

FIG. 4C illustrates a side view of an enclosed photovoltaic device with three bifocal photovoltaic panels, in accordance with one embodiment of the present invention.

FIG. 5 illustrates a front view of a modified enclosed photovoltaic device with a tracking system, in accordance with one embodiment of the present invention.

### DETAILED DESCRIPTION OF ILLUSTRATIVE EMBODIMENTS

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention, however, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

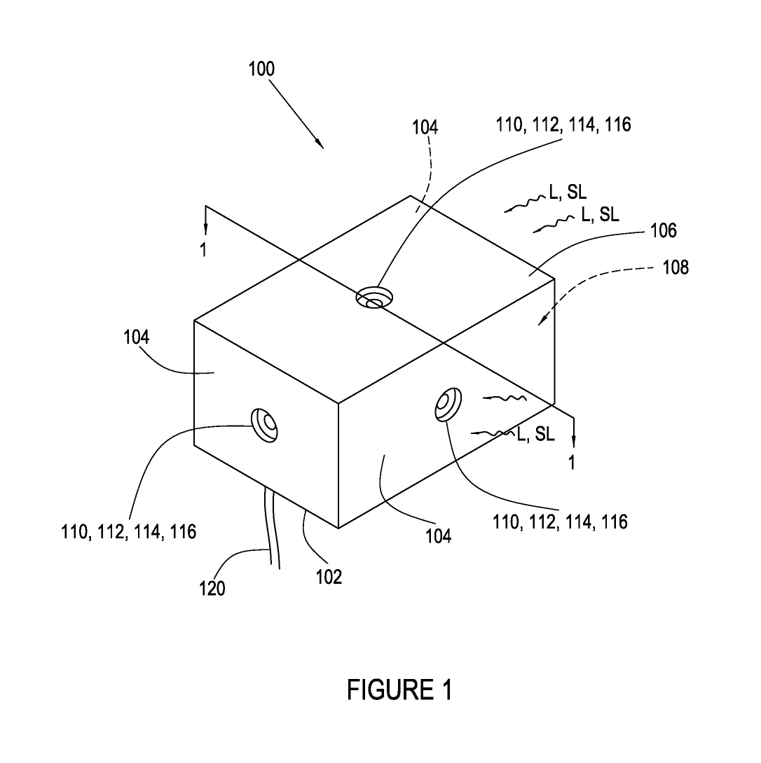

FIG. 1 illustrates an environmental front perspective view of an enclosed photovoltaic device 100, in accordance with one embodiment of the present invention.

The enclosed photovoltaic device 100 includes a base 102, 4 side walls 104, a top 106, an interior 108, a plurality of lenses 110 and one or more electrical wires 120. The light L can enter the enclosed photovoltaic device 100 from any of the 4 side walls 104 or the top 106 of the enclosed photovoltaic device 100. The light L is typically sunlight SL but can be any suitable type of light that can be converted into electrical energy by the enclosed photovoltaic device 100. The lenses 110 are disposed on the 4 side walls 104 or top 106 of the enclosed photovoltaic device 100 in any suitable combination and quantity. As illustrated in FIG. 1, the lenses 110 are disposed on 2 side walls 104 and the top 106 of the enclosed photovoltaic device 100. The lenses 110 can be a plurality of Fresnel lenses 112, a plurality of concave lenses 114, a plurality of divergent shape lenses 116 or any other suitable type of lenses. The one or more electrical wires 120 extend from the base 102 of the enclosed photovoltaic device 100 and typically provide electricity generated by the enclosed photovoltaic device 100 that can be either stored, used directly (i.e., in an island or standalone plant) or fed into a large electricity grid powered by one or more central generation plants (i.e., a grid-connected or grid-tied plant) or combined with one or more domestic electricity generators to feed into a small grid (i.e., hybrid plant) or a battery. FIG. 1 illustrates a single electrical wire 120 extending from the base 120 of the enclosed photovoltaic device 100.

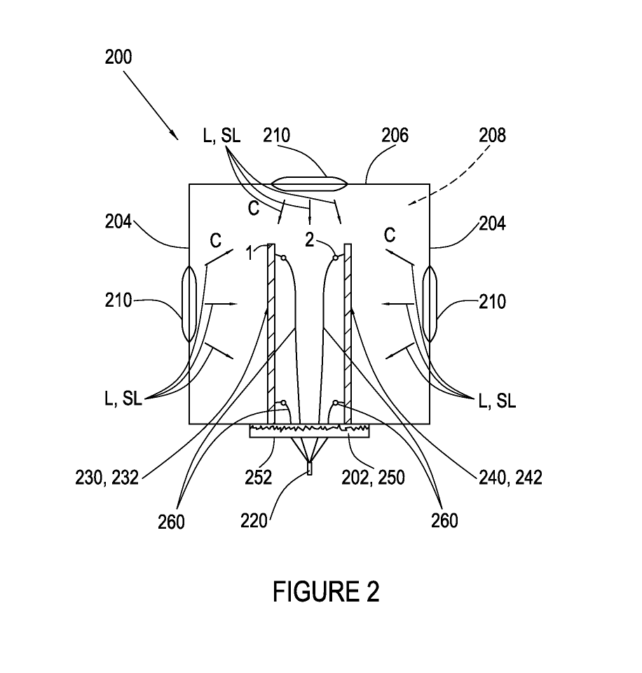

FIG. 2 illustrates a cross-sectional view of line 1-1 from FIG. 1 of an enclosed photovoltaic device 200, in accordance with one embodiment of the present invention.

The enclosed photovoltaic device 200 described and illustrated in FIG. 2 and its description is similar to the enclosed photovoltaic device 100 described and illustrated in FIG. 1 and its description and includes a base 102, 4 side walls 104, a top 106, an interior 108, a plurality of lenses 110, one or more electrical wires 120, light L and sunlight SL that is similar to a base 202, 4 side walls 204, a top 206, an interior 208, a plurality of lenses 210 and one or more electrical wires 220, light L and sunlight SL described and illustrated in FIG. 2 and its description.

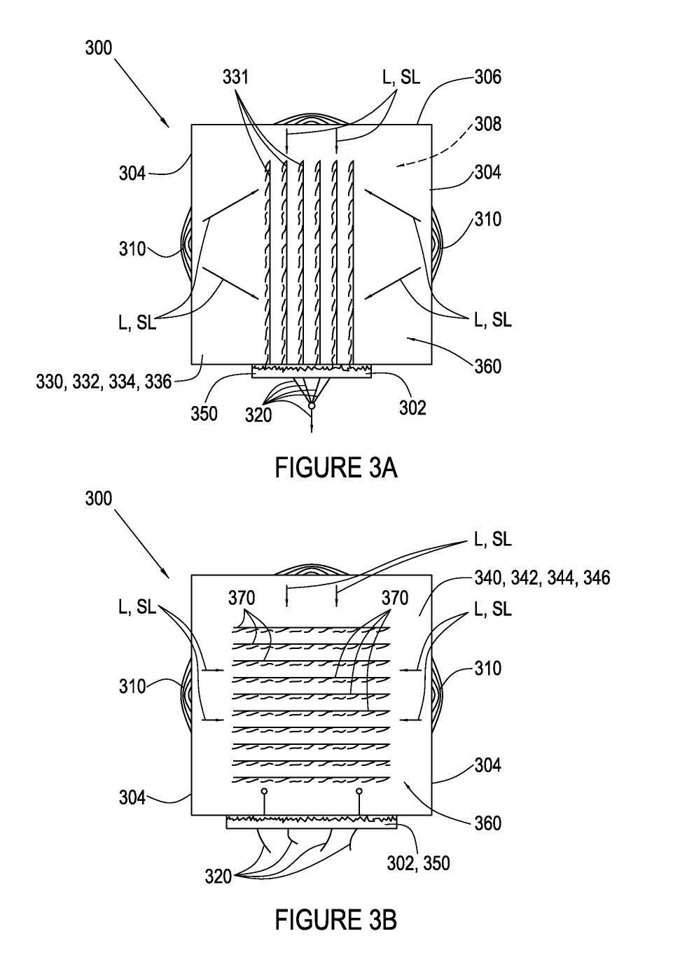

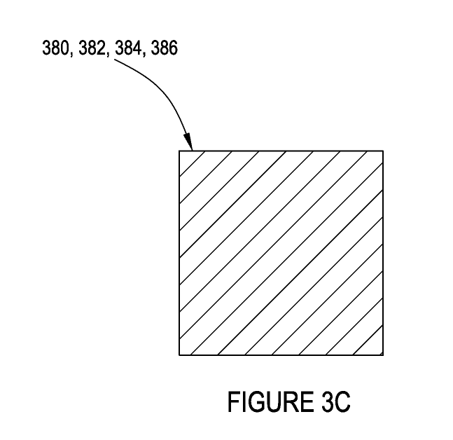

The enclosed photovoltaic device 200 additionally includes a first photovoltaic panel 230, a second photovoltaic panel 240, a heat sink 250 and a plurality of internal wiring 260. The first photovoltaic panel 230 is typically a solar panel 232 but can be any suitable type of photovoltaic panel 230 that can convert light into electrical energy. The second photovoltaic panel 240 is also typically a solar panel 242 but can be any suitable type of photovoltaic panel 240 that can convert light into electrical energy. The first photovoltaic panel 230 and the second photovoltaic panel 240 are perpendicularly vertical to the base 202 within the interior 208 of the enclosed photovoltaic device 200 and are utilized together to enhance the quantity of electrical energy generated by the enclosed photovoltaic device 200. Additional details regarding the first photovoltaic panel 230 and the second photovoltaic panel 240 are illustrated and described in subsequent FIGS. 3A and 3B. The heat sink 250 includes a fan 252 that cools the enclosed photovoltaic device 200 where heat flow from the interior 208 and the first photovoltaic panel 230 and the second photovoltaic panel 240 is expelled or absorbed from the enclosed photovoltaic device 200. The heat sink 250 is disposed on the base 202 of the enclosed photovoltaic device 200. The internal wiring 260 carries electric current produced and converted from light L received by the first photovoltaic panel 230 and the second photovoltaic panel 240 to the base 202 of the enclosed photovoltaic device 200.

FIG. 3A illustrates a front view of a first photovoltaic panel with a plurality of vertical photovoltaic cells of an enclosed photovoltaic device 300, in accordance with one embodiment of the present invention.

The enclosed photovoltaic device 300 described and illustrated in FIG. 3A and its description is similar to the enclosed photovoltaic device 200 described and illustrated in FIG. 2 and its description and includes a base 202, 4 side walls 204, a top 206, an interior 208, a plurality of lenses 210 and one or more electrical wires 220, a first photovoltaic panel 230 and a heat sink 250 that is similar to a base 302, 4 side walls 304, a top 306, an interior 308, a plurality of lenses 310 and one or more electrical wires 320, a first photovoltaic panel 330 and a heat sink 350 described and illustrated in FIG. 3A and its description.

The enclosed photovoltaic device 300 additionally includes a first photovoltaic panel 330 with a plurality of vertical photovoltaic cells 331 and a reflective mirror interior design 360. The first photovoltaic panel 330 is typically a solar panel 332 with a generally square shape 334 with a front facing 336. The vertical photovoltaic cells 331 are disposed on the front facing 336 to absorb light L that enters the enclosed photovoltaic device 300. FIG. 3A illustrates 6 vertical photovoltaic cells 331 however any quantity of vertical photovoltaic cells 331 in the range of 2 to 6 vertical photovoltaic cells 331 or any other suitable quantity can be disposed on the first photovoltaic panel 330. The reflective mirror interior design 360 includes the 4 side walls 304 and the top 306 being made of reflective mirror material 362 to enhance the light L moving within the reflective mirror interior design 360 resulting in a relatively greater amount of generated electrical energy from the vertical photovoltaic cells 331 than a traditional non-reflective mirror material design.

FIG. 3B illustrates a front view of a second photovoltaic panel with a plurality of horizontal photovoltaic cells of an enclosed photovoltaic device 300, in accordance with one embodiment of the present invention.

The enclosed photovoltaic device 300 described and illustrated in FIG. 3B and its description is similar to the enclosed photovoltaic device 200 described and illustrated in FIG. 2 and its description and includes a base 202, 4 side walls 204, a top 206, an interior 208, a plurality of lenses 210 and one or more electrical wires 220, a second photovoltaic panel 240 and a heat sink 250 that is similar to a base 302, 4 side walls 304, a top 306, an interior 308, a plurality of lenses 310 and one or more electrical wires 320, a second photovoltaic panel 340 and a heat sink 350 described and illustrated in FIG. 3B and its description.

The enclosed photovoltaic device 300 additionally includes a second photovoltaic panel 340 and a plurality of horizontal photovoltaic cells 370. The second photovoltaic panel 340 is typically a solar panel 342 with a generally square shape 344 with a front facing 346. The horizontal photovoltaic cells 370 are disposed on the front facing 346 to absorb light L that enters the enclosed photovoltaic device 300. FIG. 3B illustrates 10 horizontal photovoltaic cells 370 however any suitable quantity of horizontal photovoltaic cells 370 can be disposed on the second photovoltaic panel 340. The reflective mirror interior design 360 is also similar to the reflective mirror interior design 360 described and illustrated in FIG. 3A and its description.

FIG. 3C illustrates a front view of a solar cell 380 of an enclosed photovoltaic device, in accordance with one embodiment of the present invention.

The solar cell 380 can be utilized in place of the first photovoltaic panel 230,330 and the second photovoltaic panel 240,340 that were previously described in FIGS. 2, 3A and 3B. The solar cell 380 is a monocrystalline 382 or a multicrystalline 384 solar cell and is generally square shaped 386. The solar cell 380 is approximately 125 mm×125 mm, 156 mm×156 mm or other suitable dimensions. In contrast to the first photovoltaic panel 230,330 and the second photovoltaic panel 240,340 that were previously described in FIGS. 2, 3A and 3B, the solar cell 380 does not have any vertical photovoltaic cells 350 or horizontal photovoltaic cells 370.

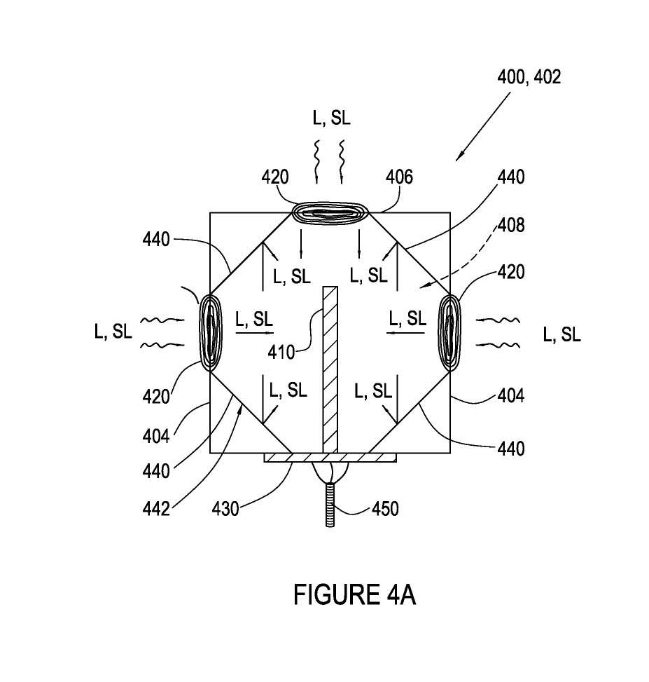

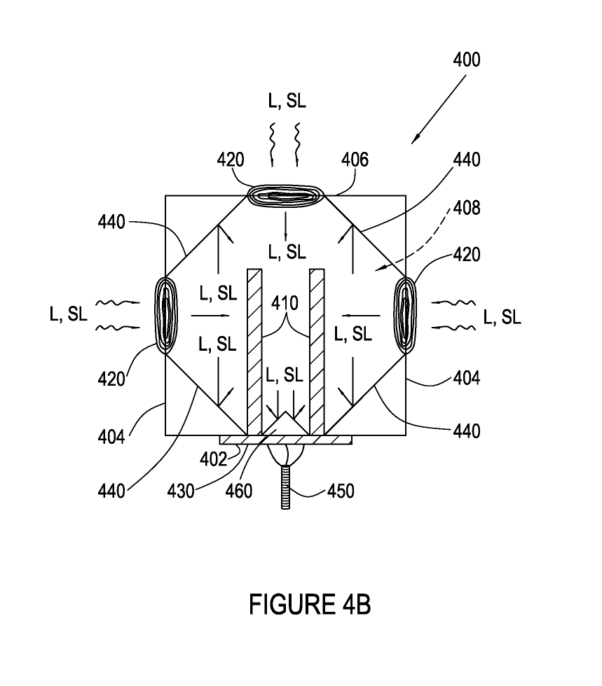

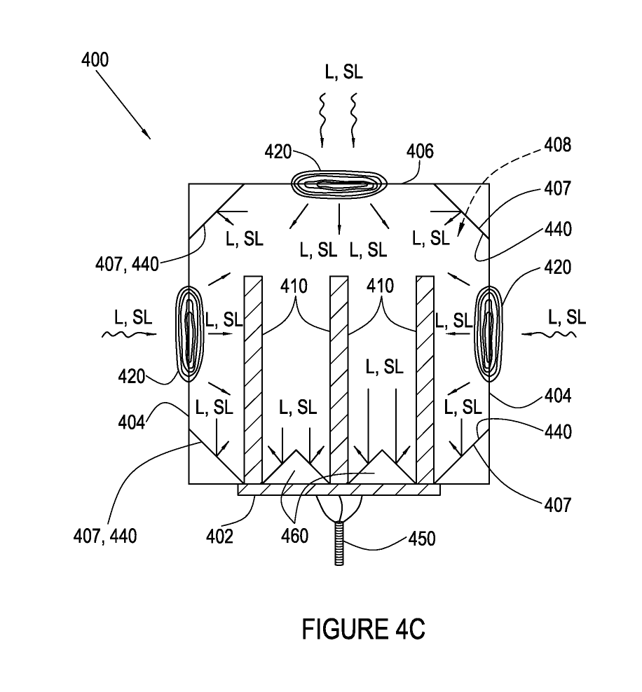

FIG. 4A illustrates a side view of an enclosed photovoltaic device 400 with one bifocal photovoltaic panel 405, in accordance with one embodiment of the present invention.

The enclosed photovoltaic device 400 includes a base 402, 4 side walls 404, a top 406, an interior 408, light L and sunlight SL, one bifocal photovoltaic panel 410, a plurality of lens 420, a Peltier cooler 430, a plurality of reflective mirrors 440 and one or more wire cords 450. The one bifocal photovoltaic panel 410 has a first surface side 412 and a second surface side 414 and can absorb light L and sunlight SL from both the first surface side 412 and the second surface side 414. The one bifocal photovoltaic panel 410 is centered in the interior 408 of the enclosed photovoltaic device 400. The plurality of lens 420 is disposed on the top 406 and four side walls 404 of the enclosed photovoltaic device 400 in any suitable combination and quantity. The Peltier cooler 430 is disposed on the base 402 of the enclosed photovoltaic device 400 and transfers heat from one side of the base 402 to the other. The plurality of reflective mirrors 440 form a general diamond shape 442 within the interior 408 of the enclosed photovoltaic device 400 and extend diagonally from the base 402 to the plurality of lens 420 and then to the top 406 of the enclosed photovoltaic device 400. The plurality of reflective mirrors 440 internally reflect light L and sunlight SL within the interior 408 of the enclosed photovoltaic device 400 to generate relatively more electricity than traditional enclosed photovoltaic devices. The one or more wire cords 450 extend from the base 402 and typically provide electricity generated by the enclosed photovoltaic device 400 that can be either stored, used directly (i.e., in an island or standalone plant) or fed into a large electricity grid powered by one or more central generation plants (i.e., a grid-connected or grid-tied plant) or combined with one or more domestic electricity generators to feed into a small grid (i.e., hybrid plant) or a battery.

FIG. 4B illustrates a side view of an enclosed photovoltaic device 400 with two bifocal photovoltaic panels 410, in accordance with one embodiment of the present invention.

The enclosed photovoltaic device 400 described and illustrated in FIG. 4B and its description is similar to the enclosed photovoltaic device 400 described and illustrated in FIG. 4A and its description and includes a base 402, 4 side walls 404, a top 406, an interior 408, a plurality of lenses 420, one or more electrical wires 450, light L and sunlight SL that is similar to a base 402, 4 side walls 404, a top 406, an interior 408, a plurality of lenses 420 and one or more electrical wires 450, light L and sunlight SL described and illustrated in FIG. 4A and its description. In contrast, FIG. 4B illustrates and utilizes two bifocal photovoltaic panels 410 instead of just one bifocal photovoltaic panel 410 illustrated in FIG. 4A. There is also an additional triangular-shaped mirror 460 set between the two bifocal photovoltaic panels 410 to provide additional reflection and generated electricity.

FIG. 4C illustrates a side view of an enclosed photovoltaic device 400 with three bifocal photovoltaic panels 410, in accordance with one embodiment of the present invention.

The enclosed photovoltaic device 400 described and illustrated in FIG. 4C and its description is similar to the enclosed photovoltaic device 400 described and illustrated in FIG. 4A and its description and includes a base 402, 4 side walls 404, a top 406, an interior 408, a plurality of lenses 420, one or more electrical wires 450, light L and sunlight SL that is similar to a base 402, 4 side walls 404, a top 406, an interior 408, a plurality of lenses 410 and one or more electrical wires 450, light L and sunlight SL described and illustrated in FIG. 4A and its description. In contrast, FIG. 4C illustrates and utilizes three bifocal photovoltaic panels 410 instead of just one bifocal photovoltaic panel 410 illustrated in FIG. 4A. There is also a pair of triangular-shaped mirror 460 set between the three bifocal photovoltaic panels 410 to provide additional reflection and generated electricity. The plurality of reflective mirrors 440 are set relatively closer to the corners 407 of the interior 408 of the enclosed photovoltaic device 400 to accommodate the relative greater space occupied by the three bifocal photovoltaic panels 410.

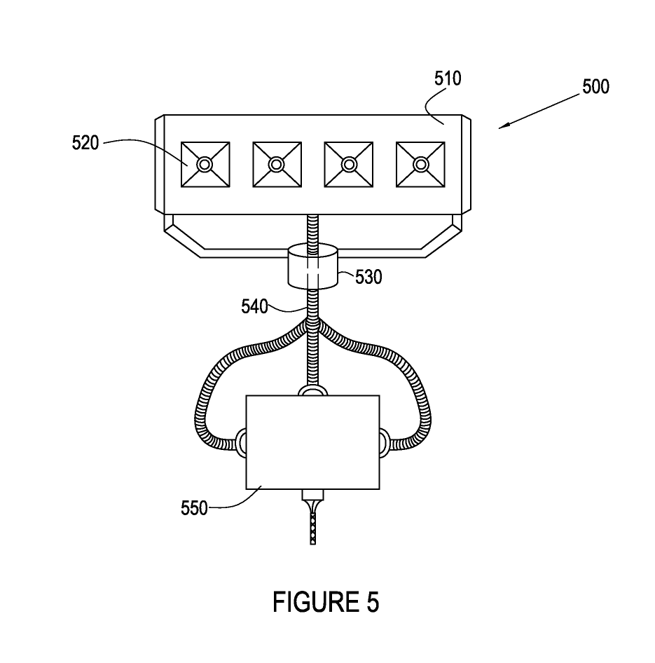

FIG. 5 illustrates a front view of an enclosed photovoltaic device 500 with a tracking system 510, in accordance with one embodiment of the present invention.

The enclosed photovoltaic device 500 includes a receiver 510, a plurality of lens 520, a tracking system 530, a plurality of fiber optic cable 540 and an enclosed photovoltaic device 550. The tracking system 510 rotates 360 degrees and assists in tracking any light L or sunlight SL. The receiver 510 receives light L and sunlight SL. The plurality of lens 520 is housed within the receiver 510 and converts the light L and sunlight SL into electrical energy. The tracking system 530 is attached under the receiver 510 and rotates 360 degrees to receive any light L or sunlight SL from a plurality of angles and a plurality of positions. The plurality of fiber optic cable 540 is attached below the tracking system 530. The enclosed photovoltaic device 550 is in communication with the tracking system 530 with the plurality of fiber optic cable 540. The enclosed photovoltaic device 550 is a similar enclosed photovoltaic device 550 illustrated and described in FIGS. 4A, 4B and 4C.

While the present invention has been related in terms of the foregoing embodiments, those skilled in the art will recognize that the invention is not limited to the embodiments described. The present invention can be practiced with modification and alteration within the spirit and scope of the appended claims. Thus, the description is to be regarded as illustrative instead of restrictive on the present invention.

What is claimed is:

1. An enclosed photovoltaic device with a base, 4 side walls, a top and an interior, comprising:
a plurality of lenses that are disposed on said 4 side walls and said top of said enclosed photovoltaic device;
one or more electrical wires that extend from said base of said enclosed photovoltaic device and provide electricity generated by said enclosed photovoltaic device that is stored;
a first photovoltaic cell with a front facing that is a solar cell with a plurality of vertical photovoltaic cells disposed on said front facing that converts light that enters into said enclosed photovoltaic device into electrical energy;
a second photovoltaic cell with a front facing that is a solar cell with a plurality horizontal photovoltaic cells disposed on said front facing that converts said light into said electrical energy;
a heat sink that is disposed on said base that includes a fan that cools said enclosed photovoltaic device where heat flow from said interior and said first photovoltaic panel and said second photovoltaic panel is expelled from said enclosed photovoltaic device;
a plurality of internal wiring that carries electric current produced and converted from said light received by said first photovoltaic cell and said second photovoltaic cell to said base of said enclosed photovoltaic device; and
a reflective mirror interior design that includes said 4 side walls and said top made of reflective mirror material to enhance said light moving within said reflective mirror interior design.

2. The device according to claim 1, wherein said lenses are a plurality of Fresnel lenses.

3. The device according to claim 1, wherein said lenses are a plurality of concave lenses.

4. The device according to claim 1, wherein said lenses are a plurality of divergent shape lenses.

5. The device according to claim 1, wherein said one or more electrical wires that extend from said base of said enclosed photovoltaic device and provide electricity generated by said enclosed photovoltaic device is used directly.

6. The device according to claim 1, wherein said first photovoltaic cell and said second photovoltaic cell are perpendicularly vertical to said base within said interior of said enclosed photovoltaic device.

7. The device according to claim 1, wherein said first photovoltaic cell and said second photovoltaic cell are utilized together to enhance a quantity of said electrical energy generated by said enclosed photovoltaic device.

8. The device according to claim 1, wherein said heat flow from said interior and said first photovoltaic cell and said second photovoltaic cell is absorbed from said enclosed photovoltaic device.

9. The device according to claim 1, wherein said reflective mirror interior design results in a greater amount of generated said electrical energy from said photovoltaic cells than a traditional non-reflective mirror material design.

10. The device according to claim 1, wherein said light enters said enclosed photovoltaic device from any said 4 side walls and said top of said enclosed photovoltaic device.

11. The device according to claim 12, wherein said light is sunlight.

12. The device according to claim 1, wherein said enclosed photovoltaic device utilizes a solar cell in place of said first photovoltaic cell.

13. The device according to claim 12, wherein said enclosed photovoltaic device utilizes said solar cell in place of said second photovoltaic cell.

14. The device according to claim 12, wherein said solar cell is a monocrystalline solar cell.

15. The device according to claim 12, wherein said solar cell is a multicrystalline solar cell.

16. The device according to claim 1, wherein said heat sink is replaced with a Peltier cooler.

17. The device according to claim 1, wherein said first photovoltaic cell and said second photovoltaic cells are bifacial photovoltaic cells.

18. The device according to claim 1, wherein said device includes a third bifacial photovoltaic cell.

19. The device according to claim 18, wherein said device includes a triangular-shaped mirror set between said first photovoltaic cell and said second photovoltaic cell and said second photovoltaic cell and said third bifacial photovoltaic cell.

20. The device according to claim 1, wherein said device includes a tracking system.
